(19) United States
(12) Patent Application Publication
(10) Pub. No.: US 2005/0094428 A1
(43) Pub. Date: May 5, 2005

(54) Non-volatile semiconductor memory device, electronic card and electronic device

(75) Inventors: Takuya Futatsuyama, Yokohama-shi (JP); Kenichi Imamiya, Ota-ku (JP); Hideo Mukai, Ota-ku (JP); Tatsuya Tanaka, Kawasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 10/939,412

(22) Filed: Sep. 14, 2004

(30) Foreign Application Priority Data
Sep. 26, 2003 (JP) 2003-334713

(51) Int. Cl. G11C 11/22

(52) U.S. Cl. 365/145

(57) ABSTRACT

A non-volatile semiconductor memory device operative to erase data on a block basis is provided. Each of blocks includes a plurality of NAND cells each having one or more electrically erasable programmable memory cells and selection transistors arranged at both ends thereof. The memory device comprises a plurality of block groups each consisting of the blocks grouped under the number of the memory cells configuring the NAND cell, which is the same as others in one block group and different from those in other block groups. A row selector is arranged to select the memory cells located on the same row in each block in the plurality of block groups. Neighbors of the blocks individually include the selection transistors not shared.

### CROSS-REFERENCE TO RELATED APPLICATION

This application is based upon and claims the benefit of priority from the prior Japanese Patent Application No. 2003-334713, filed on Sep. 26, 2003; the entire contents of which are incorporated herein by reference.

### BACKGROUND OF THE INVENTION

1. Field of the Invention

The present invention relates to a NAND-type electrically erasable programmable non-volatile semiconductor memory device.

2. Description of the Related Art

An electrically erasable programmable EEPROM has been known in the art as one of semiconductor memories. For example, a NAND-type EEPROM including NAND cells has received attention because it can be highly integrated. Each NAND cell consists of a plurality of serially connected memory cells, each of which is the unit of one bit memory. The NAND-type is utilized in a memory card to store image data output from a digital still camera, for example.

The memory cell in the NAND-type EEPROM has an FET-MOS structure that includes a floating gate and a word line layered via insulators on a semiconductor substrate that provides a channel region. The NAND cell includes a plurality of memory cells serially connected in such a manner that they share a source/drain between neighbors (JP-A-2000/222895). The source/drain corresponds to an impurity region that functions as at least one of a source and a drain.

### SUMMARY OF THE INVENTION

The present invention has an object to provide a non-volatile semiconductor memory device having an increased capacity together with an improved erase efficiency.

According to an aspect of the present invention, a non-volatile semiconductor memory device operative to erase data on a block basis is provided. Each of blocks includes a plurality of NAND cells each having one or more electrically erasable programmable memory cells and selection transistors arranged at both ends thereof. The memory device comprises a plurality of block groups each consisting of the blocks grouped under the number of the memory cells configuring the NAND cell, which is the same as others in one block group and different from those in other block groups. A row selector is arranged to select the memory cells located on the same row in each block in the plurality of block groups. Neighbors of the blocks individually include the selection transistors not shared.

### BRIEF DESCRIPTION OF THE DRAWINGS

The present invention will be more fully understood from the following detailed description with reference to the accompanying drawings, in which:

FIG. 1 is a schematic cross-sectional view of a NAND cell contained in a NAND-type EEPROM according to the embodiment;

FIG. 2 is a schematic view of a II(a)-II(b) section in FIG. 1;

FIG. 3 is an equivalent circuit diagram of the NAND cell in FIG. 1;

FIG. 4 is a block diagram outlining the structure of the NAND-type EEPROM according to the embodiment;

FIG. 5 is an equivalent circuit diagram of one of blocks in FIG. 4, in which each NAND cell includes 16 memory cells;

FIG. 6 is an equivalent circuit diagram of one of blocks in FIG. 4, in which each NAND cell includes 32 memory cells;

FIG. 7 is an equivalent circuit diagram of one of blocks in FIG. 4, which includes dummy NAND cells;

FIG. 8 is an equivalent circuit diagram of the NAND cell containing a memory cell for “0” program in NAND cell programming according to the embodiment;

FIG. 9 is a schematic view of the memory cell for “0” program in FIG. 8;

FIG. 10 is an equivalent circuit diagram of the NAND cell containing a memory cell for “1” program in NAND cell programming according to the embodiment;

FIG. 11 is a schematic view of the memory cell for “1” program in FIG. 10;

FIG. 12 is an equivalent circuit diagram of the NAND cell containing a memory cell for erase in NAND cell erasing according to the embodiment;

FIG. 13 is an equivalent circuit diagram of the NAND cell containing a memory cell for read in NAND cell reading according to the embodiment;

FIG. 14 is a graph showing a data distribution of “0” and “1”;

FIG. 15 shows a first step of erasing data stored in memory cells connected to word lines WL0-WL3;

FIG. 16 shows a second step of the same;

FIG. 17 shows a third step of the same;

FIG. 18 shows a fourth step of the same;

FIG. 19 shows a fifth step of the same;

FIG. 20 is an equivalent circuit diagram of three successive blocks in a cell array according to the embodiment;

FIG. 21 is an equivalent circuit diagram of neighboring blocks shown as a comparative example;

FIG. 22 is an equivalent circuit diagram showing a relation between a row selector and blocks according to the embodiment;

FIG. 23 is a block diagram of an alternative of the cell array according to the embodiment;

FIG. 24 is an equivalent circuit diagram of a NAND cell applicable to the embodiment;

FIG. 25 shows another embodiment applied to a digital still camera;

FIG. 26 shows the internal configuration of the digital still camera; and

FIGS. 27A to 27J show other electronic devices to which the embodiment is applied.

### DETAILED DESCRIPTION OF THE EMBODIMENTS

An embodiment of the present invention will be described based on the drawings. The embodiment is directed to a NAND-type EEPROM operative to erase data on a block basis, which has the following two major characteristics. (1) Each of block groups consists of blocks grouped under the number of memory cells configuring a NAND cell, which is the same as others in one block group and different from those in other block groups. (2) Neighbors of the blocks individually include selection transistors not shared.

The embodiment is described in accordance with the items as classified below:

### Structure of NAND-Type EEPROM According to the Embodiment

Structure of NAND cell

Structures of Cell Array and Blocks

### Operation of NAND-Type EEPROM According to the Embodiment

Programming

Erasing

Reading

### Characteristics of the Embodiment

Characteristic 1

Characteristic 2

Characteristic 3

Characteristic 4

Characteristic 5

Characteristic 6

Characteristic 7

### Applications to Electronic Card and Electronic Device

In the figures the same parts as those once explained are given the same reference numerals to omit further explanations.

### Structure of NAND-Type EEPROM According to the Embodiment

Structure of NAND cell

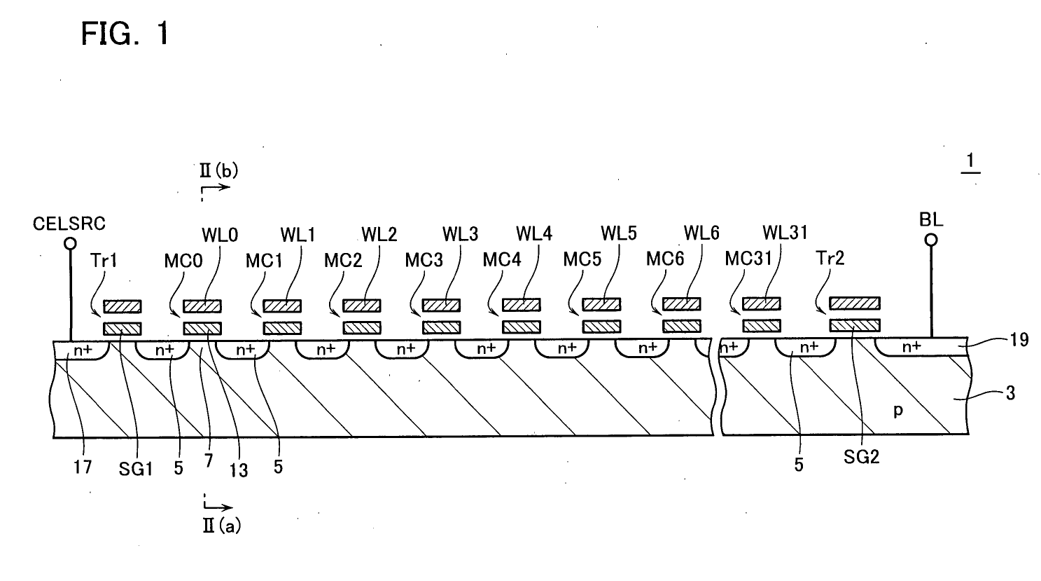

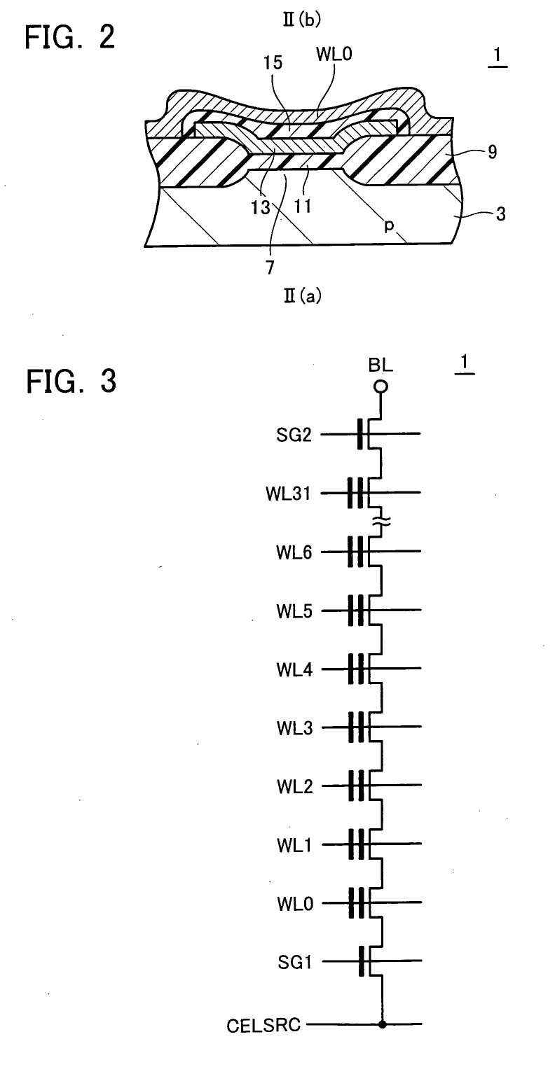

FIG. 1 is a schematic cross-sectional view of a NAND cell contained in the NAND-type EEPROM according to the embodiment. FIG. 2 is a schematic view of a II(a)-II(b) section in FIG. 1. FIG. 3 is an equivalent circuit diagram of the NAND cell in FIG. 1.

As shown in FIGS. 1-3, the NAND cell 1 has a structure including 32 memory cells MCO-31 formed in a p-type well 3 in a p⁻-type semiconductor substrate. The memory cells are non-volatile cells that are electrically data-erasable and—programmable. Each memory cell has the same configuration. For example, in the memory cell MCO, n⁺-type impurity regions (source/drain) 5 are formed in a surface of the p-type well 3 at a certain pitch. A channel region 7 is located between the impurity regions 5 in the p-type well 3. A device isolation insulator 9 is formed around the regions 5 and 7. A floating gate 13 is formed via a gate insulator 11 above the channel region 7. Finally, a word line WL0 is formed via an insulator 15 above the floating gate 13.

The NAND cell 1 includes 32 serially connected memory cells sharing a source/drain between neighbors. The number of memory cells configuring the NAND cell 1 may be equal to 8, 16, 64 or the like though it is exemplified as 32.

Selection transistors Tr1, Tr2 are located at both sides of the NAND cell 1. Formed close to the memory cell MC0 is the selection transistor Tr1 that has a selection gate line SG1. An end of the current path in the transistor Tr1 is connected via the impurity region 5 to an end of the current path in the memory cell MC0. The other end of the current path in the transistor Tr1, or a n⁺-type impurity region 17 formed in the p-type well 3, is connected to a source line CELSRC. The selection transistor Tr1 is employed to control connection and disconnection between the NAND cell 1 and the source line CELSRC.

Formed close to the memory cell MC31 is, on the other hand, the selection transistor Tr2 that has a selection gate line SG2. In the selection transistor Tr2, an end of the current pass is connected via the impurity region 5 to an end of the current path in the memory cell MC31. The other end of the current path in the transistor Tr2, or a n⁺-type impurity region 19 formed in the p-type well 3, is connected to a bit line BL. The transistor Tr2 is employed to control connection and disconnection between the NAND cell 1 and the bit line BL.

Structures of Cell Array and Blocks

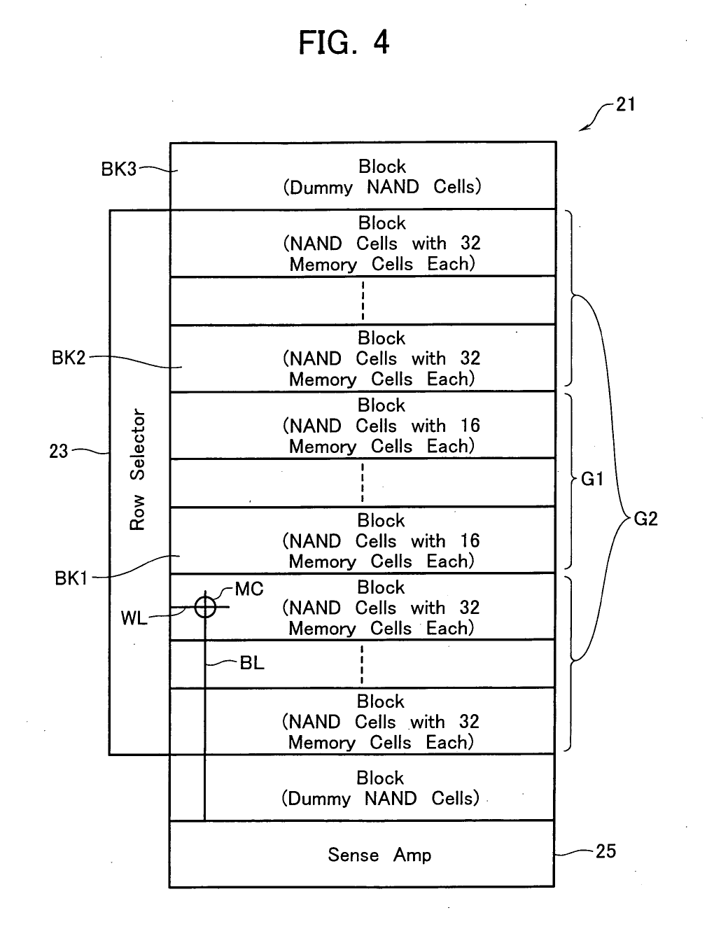

FIG. 4 is a block diagram outlining the structure of the NAND-type EEPROM according to the embodiment. This NAND-type EEPROM includes a cell array 21 and peripherals. Among the peripherals, FIG. 4 shows a row selector (row decoder) 23 and a sense amp 25.

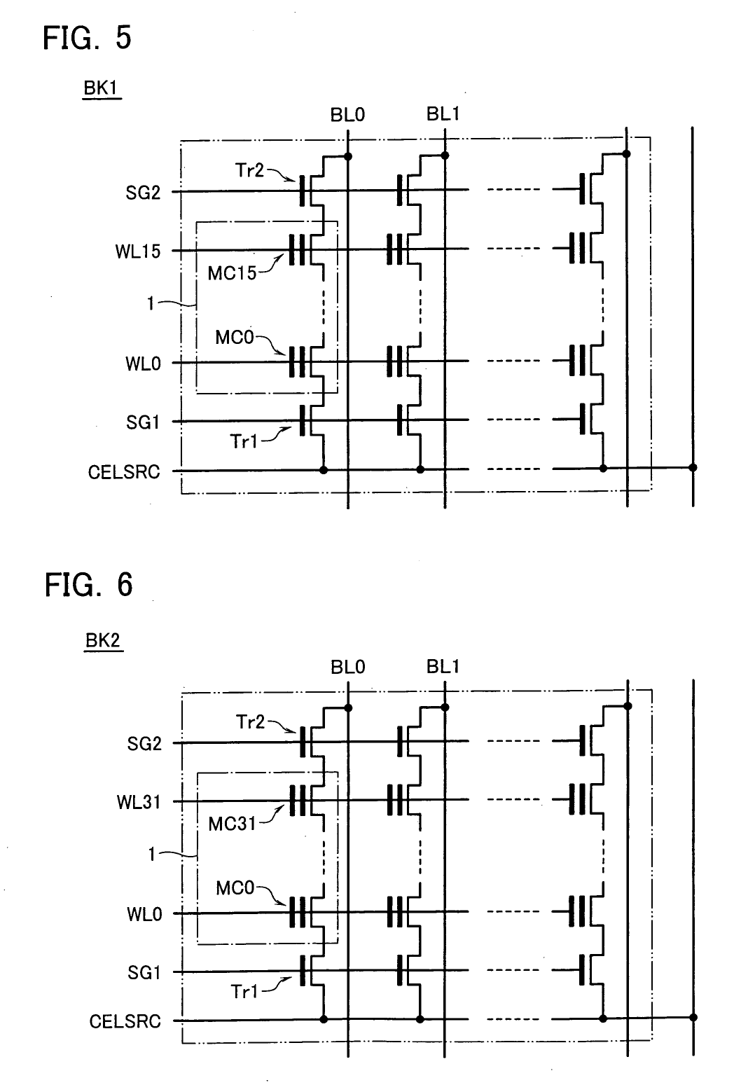

The cell array 21 has a structure with a plurality of blocks arranged along the column. A block is the unit for erasing data. The cell array 21 is arranged in the p-type well 3 of FIG. 1. In other words, blocks configuring the cell array 21 are all arranged in a single p-type well 3. In a block BK1, the number of memory cells MC configuring a NAND cell is equal to 16. FIG. 5 is an equivalent circuit diagram of the block BK1. NAND cells are arranged along the row by the number equal to that of bit lines BL. The block BK1 includes 16 word lines (WL0-WL15). Memory cells MC on the same row in the block BK1 are commonly connected to the word line corresponding to that row. A group of the blocks BK1 corresponds to a block group G1 (an example of the first block group). The block group G1 is located at the center of the cell array 21.

Blocks BK2 are arranged such that they sandwich the block group G1 therebetween. FIG. 6 shows an equivalent circuit diagram of the blocks BK2. In the block BK2, the number of memory cells MC configuring a NAND cell 1 is equal to 32. The block BK2 includes 32 word lines (WL0-WL31). A group of the blocks BK2 corresponds to a block group G2 (an example of the second block group).

The embodiment is provided with the block groups G1 and G2. Therefore, the cell array 21 in the embodiment includes a plurality of block groups arranged along the column. Each block group consists of the blocks grouped under the number of the memory cells MC configuring the NAND cell 1, which is the same as others in one block group and different from those in other block groups. The row selector 23 is operative to select the memory cells located on the same row in each block in the plurality of block groups.

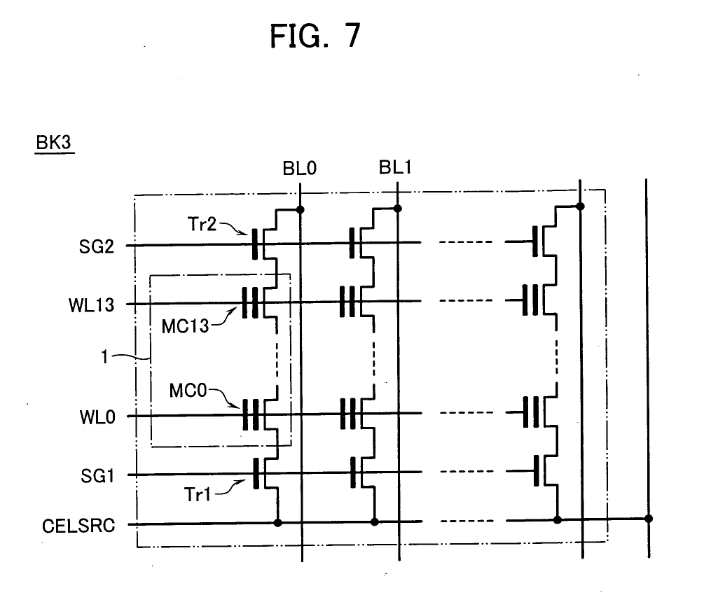

Two blocks arranged at both ends of the cell array 21 along the column correspond to blocks BK3. The blocks BK3 are blocks consisting of dummy NAND cells. FIG. 7 shows an exemplary equivalent circuit diagram of the block BK3. The number of the memory cells configuring the dummy NAND cell (NAND cell 1 in the block BK3) is equal to 14, for example, with 14 word lines (WL0-WL13).

A role of the dummy NAND cell is described herein. As in the cell array 21 the memory cells MC are arranged in matrix, the cell array 21 has a periodic layout pattern. The layout pattern is formed by patterning films of insulator and conductor using lithography and etching. As the periodicity of the layout pattern is broken at both ends of the cell array 21, a desired patterning is hardly achieved there. Therefore, at both ends of the cell array 21, dimensions of the memory cell MC can be hardly controlled, and short circuits between adjacent wires and broken wires are easily caused. Accordingly, the NAND cells in the blocks located at both ends of the cell array 21 along the column are designed as dummy. The memory cells MC in the dummy NAND cell are not utilized to store data but employed as buffers for patterning. As the dummy NAND cells are employed for such the purpose, the word lines in the dummy NAND cells are not connected to the row selector 23.

### Operation of NAND-Type EEPROM According to the Embodiment

Programming

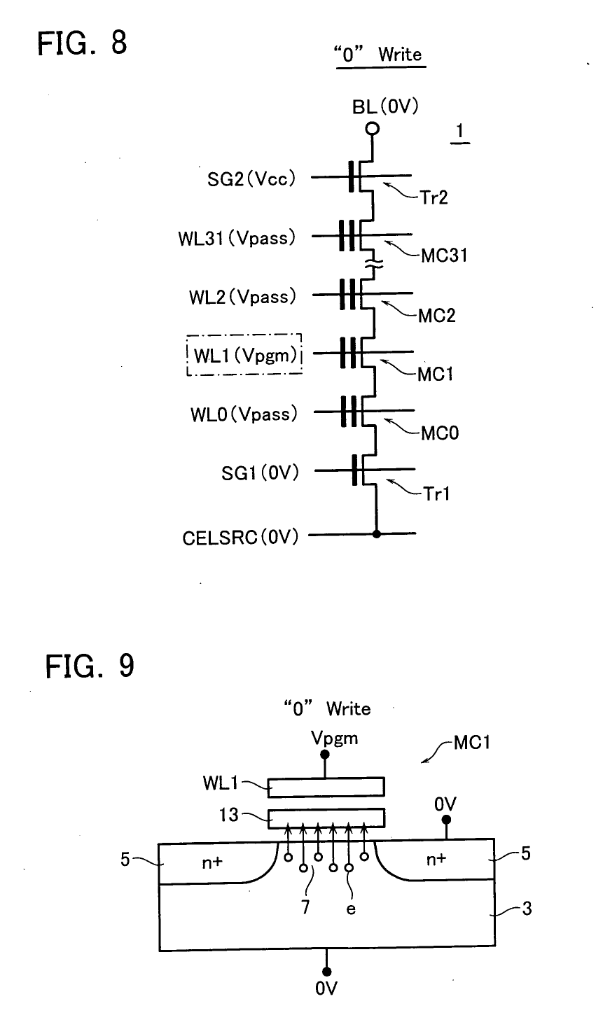

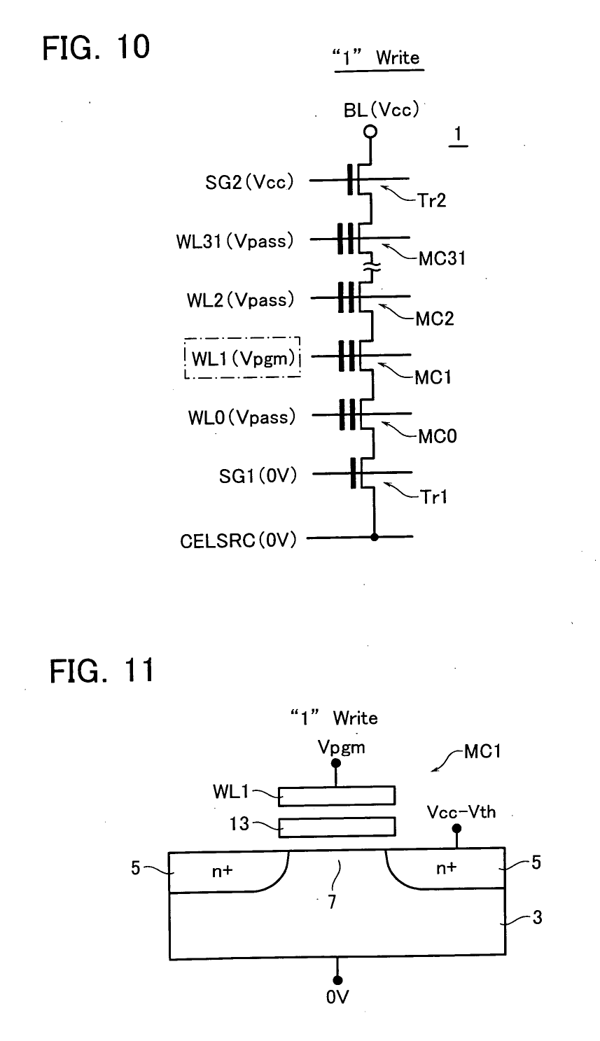

Operation of program is described with reference to FIGS. 8-11. FIG. 8 is an equivalent circuit diagram of the NAND cell 1 containing a memory cell for “0” program, and FIG. 10 is that for “1” program. The NAND cell 1 in FIGS. 8 and 10 includes 32 memory cells. FIG. 9 is a schematic view of the memory cell for “0” program, and FIG. 11 is that for “1” program.

Program is performed after the NAND cell 1 is erased or the threshold of each memory cell in the NAND cell 1 is turned into a negative voltage state. Program is performed in an order beginning from the memory cell MC0 arranged close to the source line CELSRC. An example of programming the memory cell MC1 is described.

For “0” program, as shown in FIGS. 8 and 9, Vcc (supply voltage) is applied to the selection gate line SG2 to turn on the selection transistor Tr2, and 0V (ground voltage) is applied to the bit line BL. The selection gate line SG1 is at 0V, which keeps the selection transistor Tr1 off.

Then, a high voltage Vpgm (approximately 20V) is applied to the word line WL1 for the memory cell MC1, and an intermediate voltage Vpass (approximately 10V) is applied to other word lines. The voltage on the bit line BL is equal to 0V and accordingly transferred to the channel region 7 in the selected memory cell MC1. Thus, the voltage on the channel region 7 is kept at 0V.

A large potential between the word line WL1 and the channel region 7 causes a tunnel current to inject electrons e into the floating gate 13 of the memory cell MC1. As a result, the threshold of the memory cell MC1 turns into a positive state (“0” programmed state).

On the other hand, for “1” program, FIGS. 10 and 11 are employed to describe mainly on different points from “0” program. First, Vcc (supply voltage), for example, is applied to the bit line BL. As the voltage on the selection gate line SG2 is equal to Vcc, when the voltage on the channel region 7 reaches Vcc minus Vth (Vcc-Vth; Vth denotes the threshold voltage of the selection transistor Tr2), the selection transistor Tr2 is cut off. Therefore, the channel region 7 turns into a floating state at a voltage of Vcc-Vth.

When the high voltage Vpgm (20V) is applied to the word line WL1 and the intermediate voltage Vpass (10V) to other word lines, the voltage on the channel region 7 is boosted up from Vcc-Vth to 8V, for example, through capacitive coupling between each word line and the channel region 7.

As the voltage on the channel region 7 is boosted to a high voltage, the word line WL1 and the channel region 7 have a small potential difference therebetween, different from “0” program. Accordingly, no electrons due to the tunnel current are injected into the floating gate 13 of the memory cell MC1. Therefore, the threshold of the memory cell MC1 is retained in a negative state (“1” programmed state).

When programming is performed to a batch of memory cells commonly connected to one word line (for example, simultaneous programming of 2 k-byte or 512-byte data), a faster programming can be achieved.

Erasing

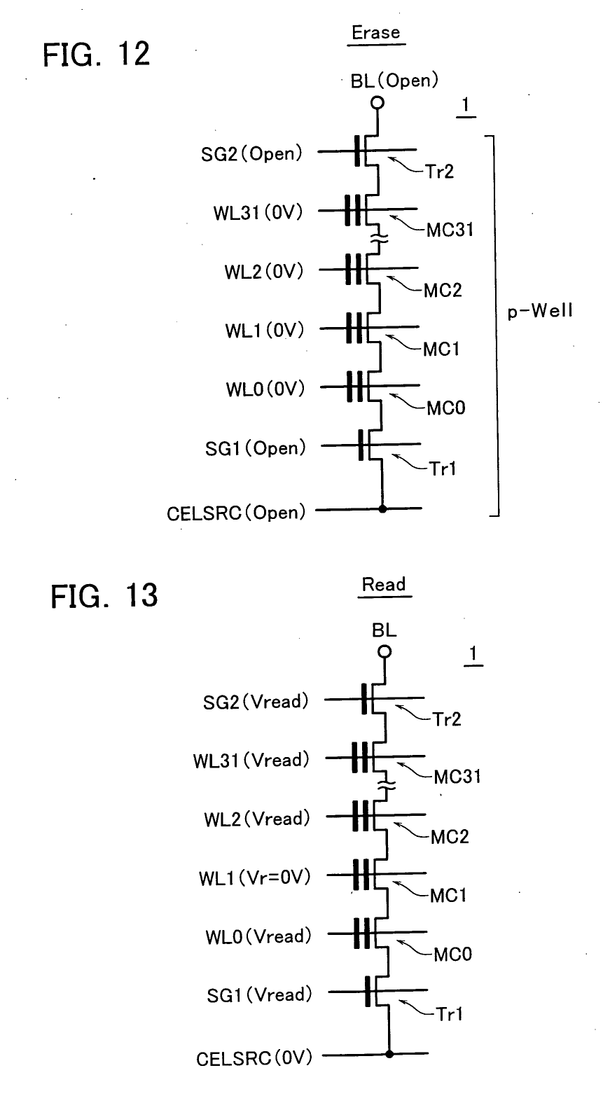

FIG. 12 is an equivalent circuit diagram of the NAND cell for erasing. Erase is simultaneously performed to all memory cells in the selected block. While all word lines in the selected block are kept at 0V, a high voltage Vera (of 22V, for example) is applied to the p-type well 3 (FIG. 1). On the other hand, the bit lines BL, the source lines CELSRC, the word lines in non-selected blocks, and the selection gate lines in all blocks are floated. Consequently, in all memory cells MC in the selected block BK, electrons in the floating gates are discharged as the tunnel current to the p-type well 3. As a result, the threshold voltages of these memory cells are shifted toward negative.

Reading

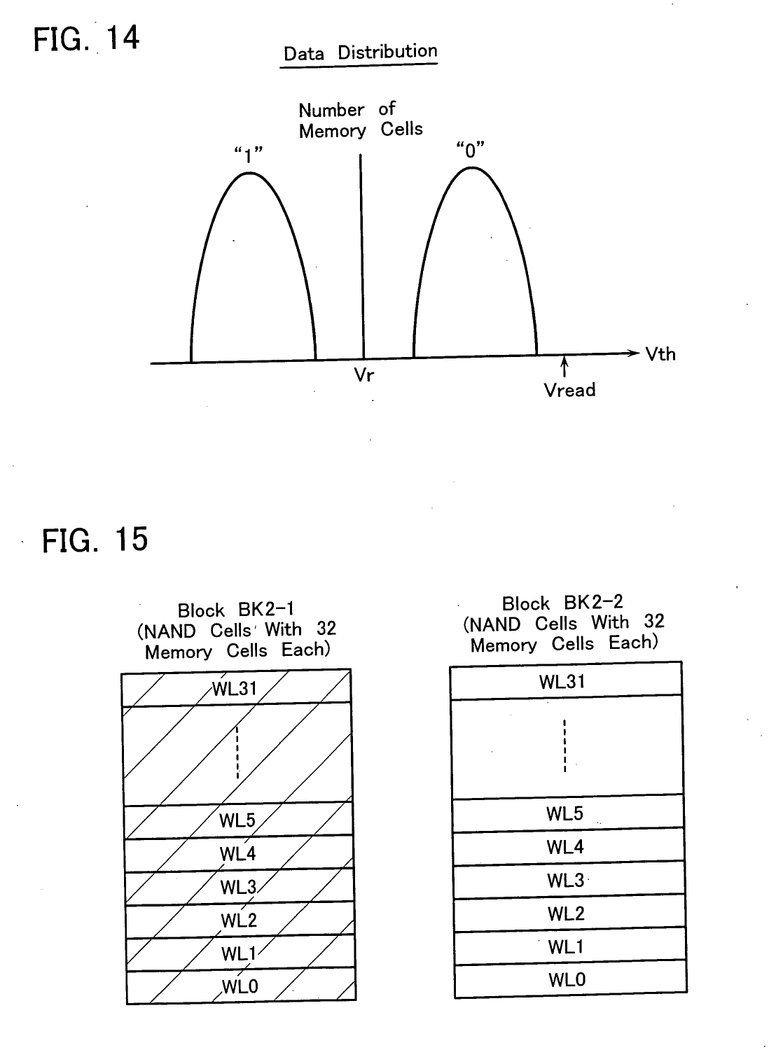

FIG. 13 is an equivalent circuit diagram of the NAND cell 1 containing a memory cell for read. FIG. 14 is a graph showing a data distribution of “0”, and “1”, with the horizontal axis indicating a threshold voltage and the vertical axis indicating the number of memory cells. As for operation of read, the word line WL1 for the memory cell MC1 selected for read is set at a voltage Vr (of 0V, for example). In addition, an intermediate voltage for read, Vread, slightly higher than the supply voltage, is applied to word lines WL0, 2-31 and selection gate lines SG1, 2 for memory cells not selected. Under this condition, it is detected if current flows into the memory cell MC1 selected for read. If the data stored in the memory cell MC1 is “0”, as the memory cell MC1 is kept off, the bit line BL is not discharged. If it is “1”, as the memory cell MC1 is kept on, the bit line BL is discharged.

### Characteristics of the Embodiment

Characteristic 1

The present embodiment is provided with the block group G1 that is the group of the blocks BK1, and the block group G2 that is the group of the blocks BK2. Each block group consists of the blocks grouped under the number of the memory cells configuring the NAND cell, which is the same as others in one block group and different from those in other block groups. This is effective to achieve an increased capacity together with an improved erase efficiency. This characteristic is described in detail with reference to an example of erasing data stored in the memory cells that are connected to the word lines WL0-WL3. FIGS. 15-19 illustrate the erasing.

The unit for programming and reading data is called a page. In the NAND-type, a group of the memory cells commonly connected to one word line corresponds to a page. Therefore, in the case of 32 word lines, there are 32 pages. (In practice, of the bit lines connected to the memory cells that are commonly connected to one word line, one-half bit lines are employed for one reading. Accordingly, in the case of 32 word lines, there are 64 pages. Thus, in the case of a block capacity of 128 k bytes and 32 word lines, there is a page capacity of 2 k bytes.)

As shown in FIG. 15, a block BK2-1 is a block that is utilized to store data. On the other hand, a block BK2-2 is an empty block, or a block that is not utilized to store data. In the NAND-type, data is erased on a block basis. Accordingly, erasing data stored in the memory cells connected to the word lines WL0-WL3 also erases data stored in the memory cells connected to the word lines WL4-WL31. In such the case, data erasing is performed as follows.

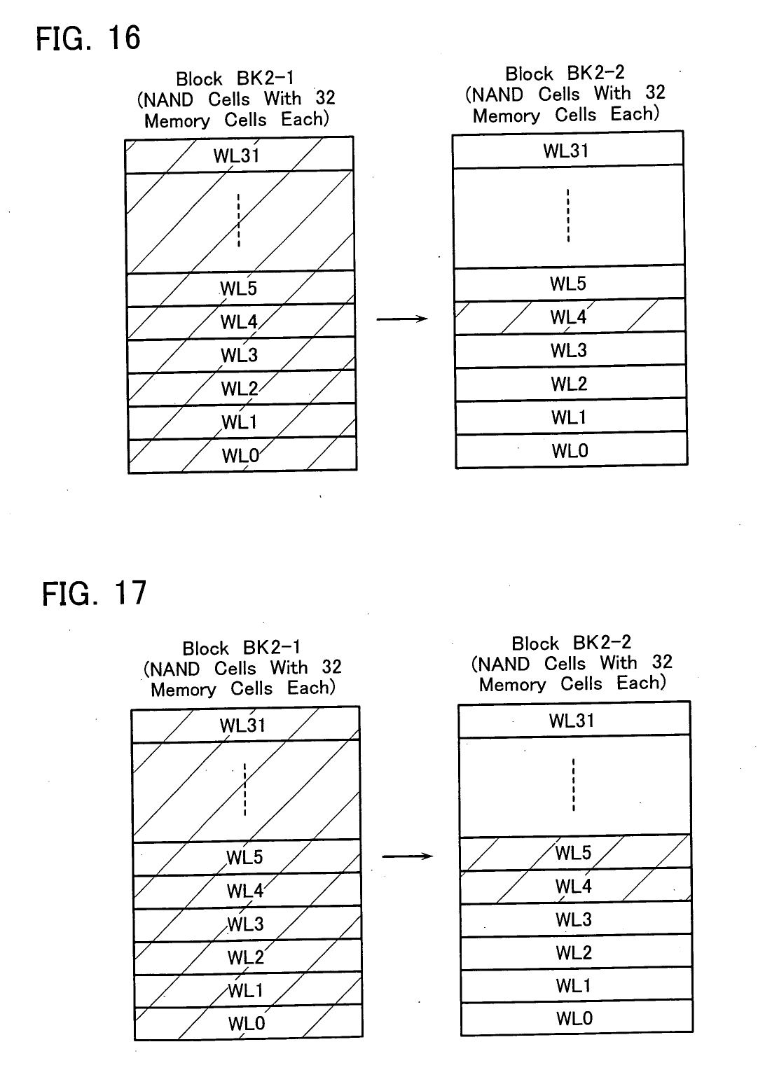

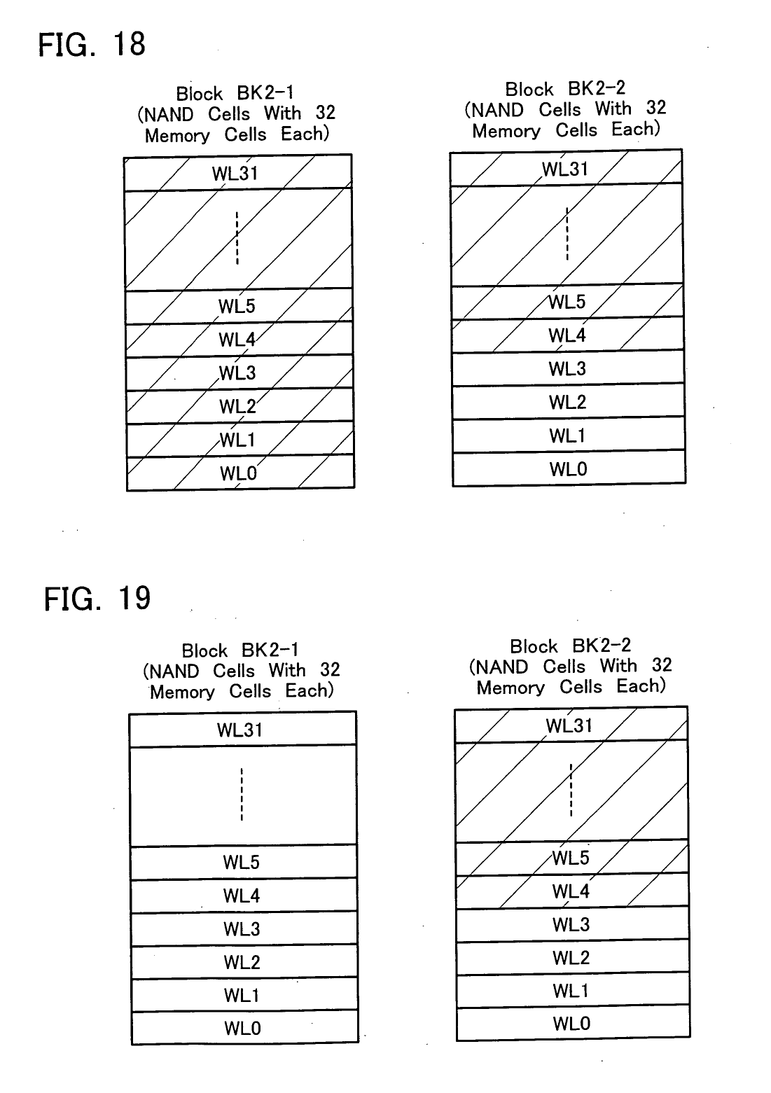

As shown in FIG. 16, data stored in the memory cell connected to the word line WL4 is read and written in the block BK2-2. Then, as shown in FIG. 17, data stored in the memory cell connected to the word line WL5 is operated similarly. Subsequently, data stored in the memory cells connected to the word line WL6-WL31 is operated similarly. FIG. 18 shows a state after these operations are completed. Then, as shown in FIG. 19, data stored in the memory cells in the block BK2-1 is erased. As above, the data stored in the memory cells connected to the word lines WL0-WL3 is erased. When data is programmed in the memory cells connected to the word lines WL0-WL3 in the block BK2-2, the word lines WL0-WL3 are selected for programming.

When the data stored in the memory cells connected to the word lines WL0-WL3 is erased as above, operations of 28 reading, 28 programming and one erasing are required. Thus, the larger the size of the block or the unit for erasing, the less the efficiency on erasing small capacity data.

Image data and musical data has a mass capacity, which enlarges the capacity of the NAND-type and increases the number of the memory cells configuring the NAND cell accordingly. The data, however, includes large capacity data and small capacity data in mixture. Therefore, when the number of the memory cells configuring the NAND cell is increased, the number of operations of reading and writing for the purpose of erasing small capacity data is increased inefficiently.

In such the case, for the small capacity data, the embodiment utilizes the block BK1 including the NAND cells each containing 16 memory cells (FIG. 4). Thus, the data stored in the memory cells connected to the word lines WL0-WL3 can be erased through operations of 12 reading, 12 programming and one erasing with an improved erasing efficiency. To the contrary, for the large capacity data, the embodiment utilizes the block BK2 including the NAND cells each containing 32 memory cells with achievement of the mass capacity.

Characteristic 2

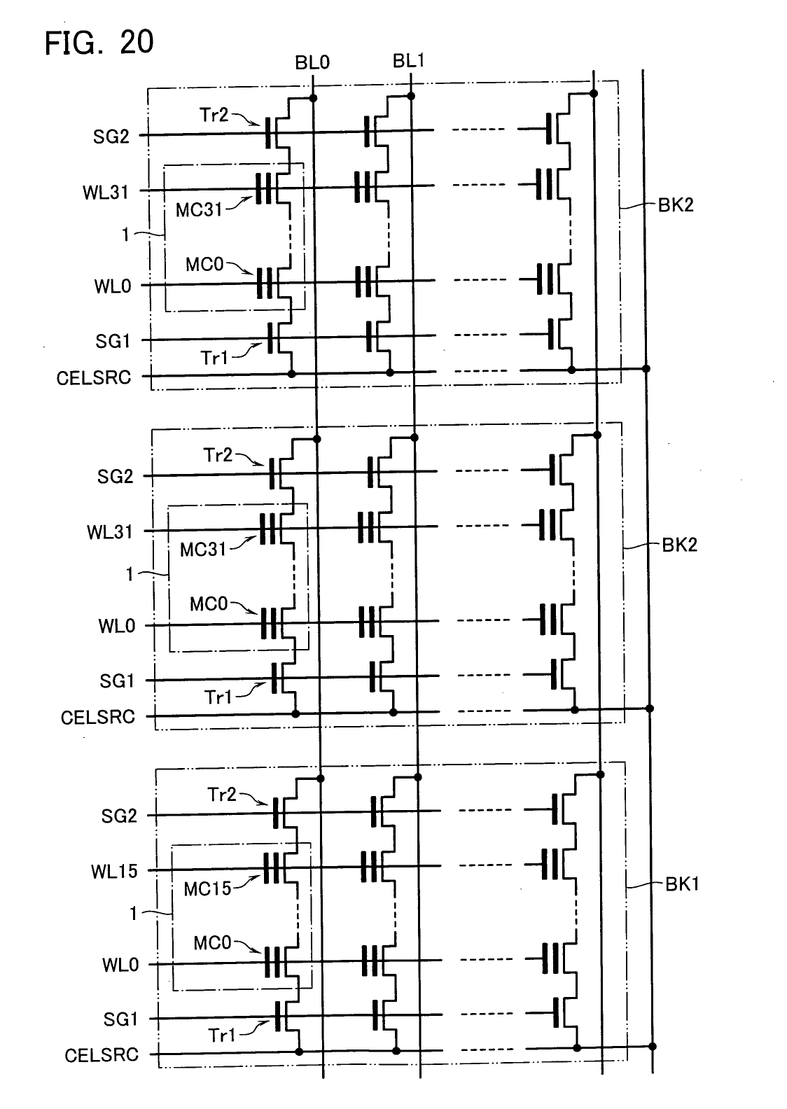

In the embodiment, neighbors of the blocks individually include the selection transistors, which are thus not shared. This is effective to reduce the number of failed memory cells when an over program occurs. Three successive blocks BK2, BK2 and BK1 are exemplified below in detail. FIG. 20 is an equivalent circuit diagram of these blocks. As selection transistors Tr1, Tr2 are assigned to each of the blocks, neighbors of the blocks do not share any selection transistors. For example, the selection transistor Tr1 in the block BK2 and the selection transistor Tr2 in the block BK1 are individually provided.

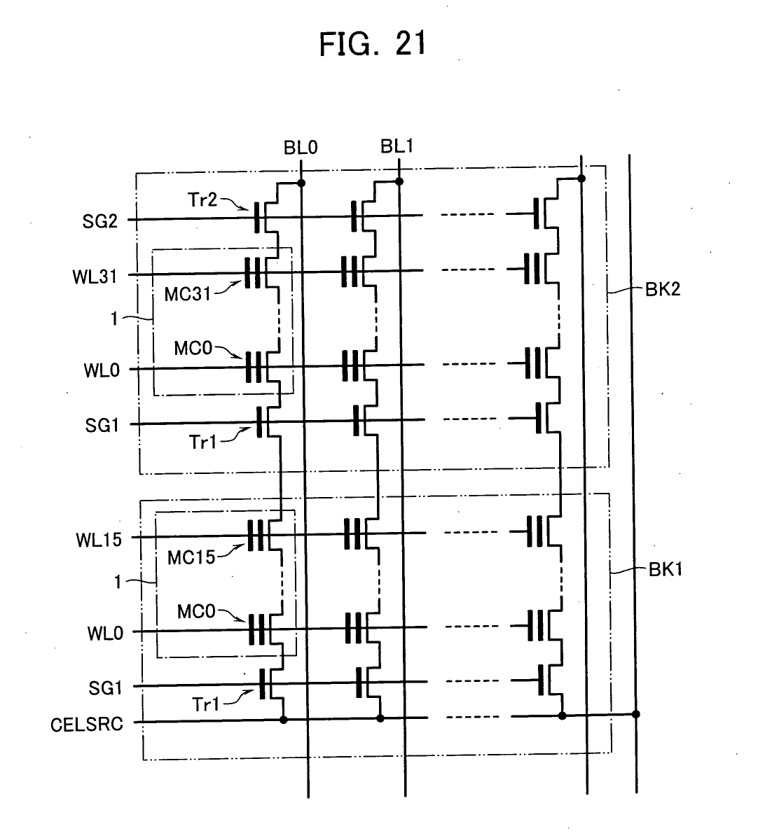

There is another NAND-type EEPROM that shares the selection transistors (for example, JP-A-2000/222895, FIG. 14). In this case, as shown in FIG. 21, the selection transistor Tr2 in the block BK1 and the source line CELSRC in the block BK2 are omitted. In addition, the NAND cell 1 in the block BK1, the selection transistor Tr1 in the block BK2 and the NAND cell 1 in the block BK2 are connected serially.

In the structure of FIG. 21, however, the number of failed memory cells increases when an over program occurs. In the case of the over program, the “0”-programmed memory cell has an excessive larger threshold. In the NAND cell, programming is performed to a batch of memory cells commonly connected to one word line (for example, simultaneous programming of 2 k-byte or 512-byte data) to achieve a faster programming. Among the memory cells commonly connected, programming is repeated to the memory cell for “1” program until its threshold reaches one that corresponds to the “0”-programmed value. For the memory cell that has a threshold reached to a desired value, through the same operation as “1” program, the bit line voltage is elevated to prevent any more program from occurring.

Occasionally, the threshold of a certain memory cell (for example, the memory cell MC2 of FIG. 13) may be elevated over the intermediate voltage for reading, Vread (FIG. 14) (over programmed). In such the occasion, even if the intermediate voltage for reading, Vread, is applied to the word line WL2 for the non-selected memory cell MC2 on reading, the non-selected memory cell MC2 connected to the word line WL2 can not be turned on. In this case, not only that memory cell but also all other memory cells belonging to the same NAND cell 1 may be failed. In the structure of the comparative example shown in FIG. 21, there are 48 memory cells between the bit line BL and the source line CELSRC. Accordingly, if an over program occurs, 48 memory cells may be failed possibly.

To the contrary, as shown in FIG. 20, in the embodiment neighbors of the blocks do not share the selection transistors. Therefore, there are 32 or 16 memory cells between the bit line BL and the source line CELSRC. Accordingly, even if an over program occurs, the number of failed memory cells can be reduced to 32 or 16, which is less than that of the comparative example of FIG. 21.

Characteristic 3

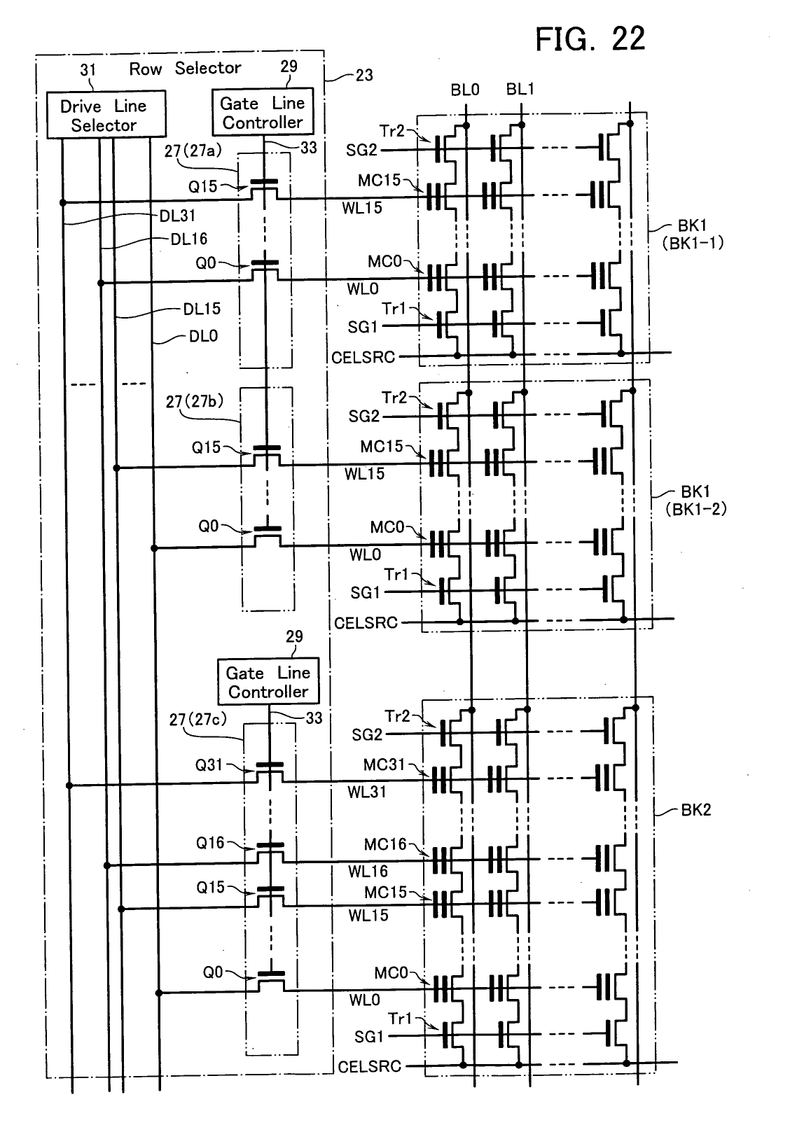

In the embodiment, the number of the memory cells configuring the NAND cell is equal to 16 (an example of m) in each block BK1 in the block group G1 (an example of the first block group) shown in FIG. 4. In addition, the number of the memory cells configuring the NAND cell is equal to 32 (an example of n) in each block BK2 in the block group G2 (an example of the second block group). Thus, the relation of n=km (k is an integer of 2 or more) is established between them. Accordingly, two (an example of k) blocks in the block group G1 (an example of the first block group) and one block in the block group G2 (an example of the second block group) can share the drive lines. Therefore, it is possible to suppress an increase in the area of the row selector 23 even if the number of blocks increases. This characteristic is described in detail with reference to FIG. 22.

FIG. 22 is an equivalent circuit diagram showing a relation between the row selector and the blocks according to the embodiment. The row selector 23 includes block selectors 27, gate line controllers 29 and a drive line selector 31. The block selectors 27 are provided corresponding to the respective blocks. The block selector 27 includes transfer transistors Q by the number the same as that of the word lines in the corresponding block. For example, the block selector 27a includes the 16 transfer transistors Q0-Q15. A block is selected by turning on a gate of the transfer transistor Q in the block selector 27 corresponding to that block.

One of the source/drain of the transfer transistor Q is connected to the corresponding word line of the word lines WL0-31, and the other is connected to the corresponding drive line of the drive lines DL0-31. The drive line is employed to supply a voltage to the corresponding word line. The 32 drive lines DL0-31 are selectively driven by the drive line selector 31. The transfer transistor Q is employed as a switch for connecting the word line to the drive line. The gates of the transfer transistors Q are commonly connected to a gate line 33, which is controlled by the gate controller 29.

In the embodiment, one block BK2 and two blocks BK1 can share the drive lines DL0-31 because the number of memory cells configuring the NAND cell is equal to 32 in the block BK2 while it is equal to 16 in the block BK1.

The number of the drive lines corresponding to the block BK1 (32 lines) is different from that in BK2 (16 lines). Accordingly, the drive line selector 31 may be provided individually for the block BK1 and for the block BK2. In such the case, however, the number of the drive line selectors 31 increases and results in an increased area occupied by the row selector 23. In the embodiment, the drive lines DL0-31 (the drive line selector 31) are shared to prevent the area occupied by the row selector 23 from increasing.

Characteristic 4

As shown in FIG. 22, according to the embodiment, in the block selectors 27a and 27b corresponding to two (an example of k) blocks BK1, gate electrodes of the transfer transistors Q0-Q15 are commonly connected through the gate line 33. In this case, with the use of the gate line controller 29 and the drive line selector 31, the word lines in a desired one of the blocks BK-1 and BK-2 can be selected. Accordingly, in the embodiment, one gate line controller 29 can be employed for two block selectors 27. This is effective to suppress an increase in the gate line controllers 29 and, also from this point, prevent the area occupied by the row selector 23 from increasing.

Characteristic 5

As shown in FIG. 4, in the embodiment, the number of the memory cells configuring the NAND cell is equal to a power of two such as 16 and 32. Therefore, if data is represented with a binary number in a non-volatile semiconductor memory device, row addresses can be assigned effectively.

Characteristic 6

The block BK1 is assigned as a storage region for a product-specified ID (a serial number given to every product to indicate when and where the product is manufactured) of a semiconductor chip containing the NAND-type EEPROM according to the embodiment. The block BK1 is also assigned as a storage region for a parameter defining circuit operation of the NAND-type EEPROM. A data amount of the ID or the parameter is smaller than the capacity of the block BK2. Accordingly, if such the data is stored in the block BK2, a large part of the capacity of the block BK2 is not utilized. The ID and the parameter should not be erased and accordingly they should not be stored together with general data in the block. In such the case, the ID and the parameter are stored in the block BK1 with a relatively small capacity to utilize the cell array 21 effectively. The above parameter is detailed in U.S. Pat. No. 10,241,468.

Characteristic 7

As shown in FIG. 4, the block group G2 (an example of the second block group) in the embodiment is divided into two and located separately, interposing the block group G1 (an example of the first block group) therebetween. As described in the characteristic 6, the block group G1 is employed to store the ID and the parameter that should not be erased. The cell array 21 has a better process yield at the center than those at both ends. Accordingly, in the embodiment the ID and the parameter can be stored in such regions that are hardly turned into failed blocks.

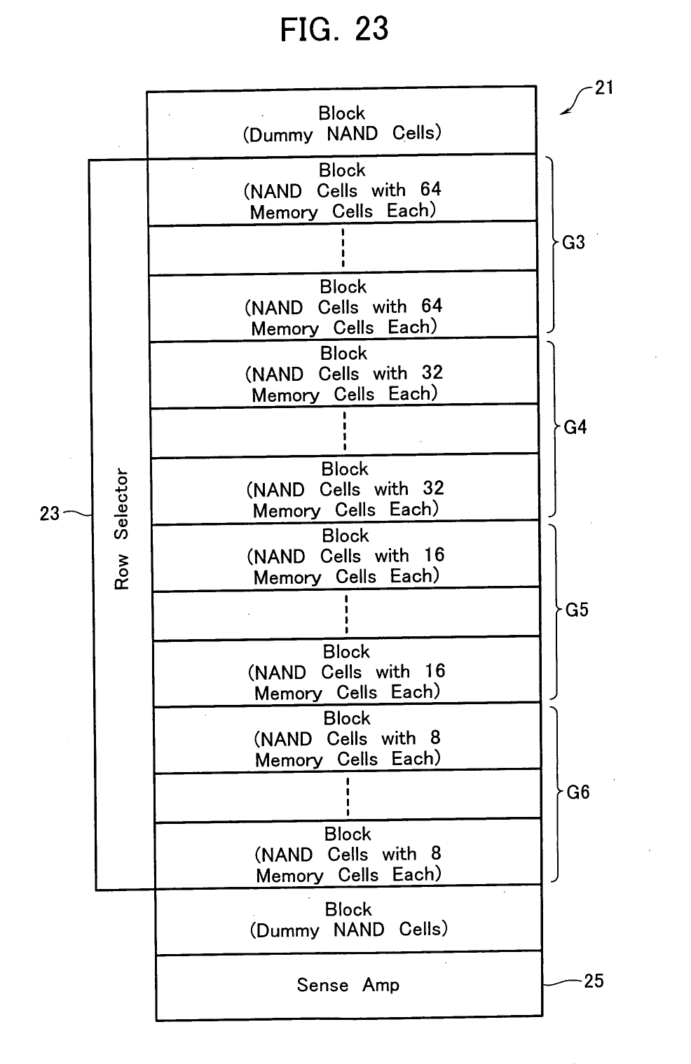

Although the example with two block groups (block groups G1, G2) is explained in FIG. 4, the number of block groups is arbitrary. For example, as shown in FIG. 23, the cell array 21 can be applied to the embodiment. The cell array 21 shown in FIG. 23 comprises a block group G3 of NAND cells each including 64 memory cells; a block group G4 of NAND cells each including 32 memory cells; a block group G5 of NAND cells each including 16 memory cells; a block group G6 of NAND cells each including 8 memory cells; and blocks of dummy NAND cells.

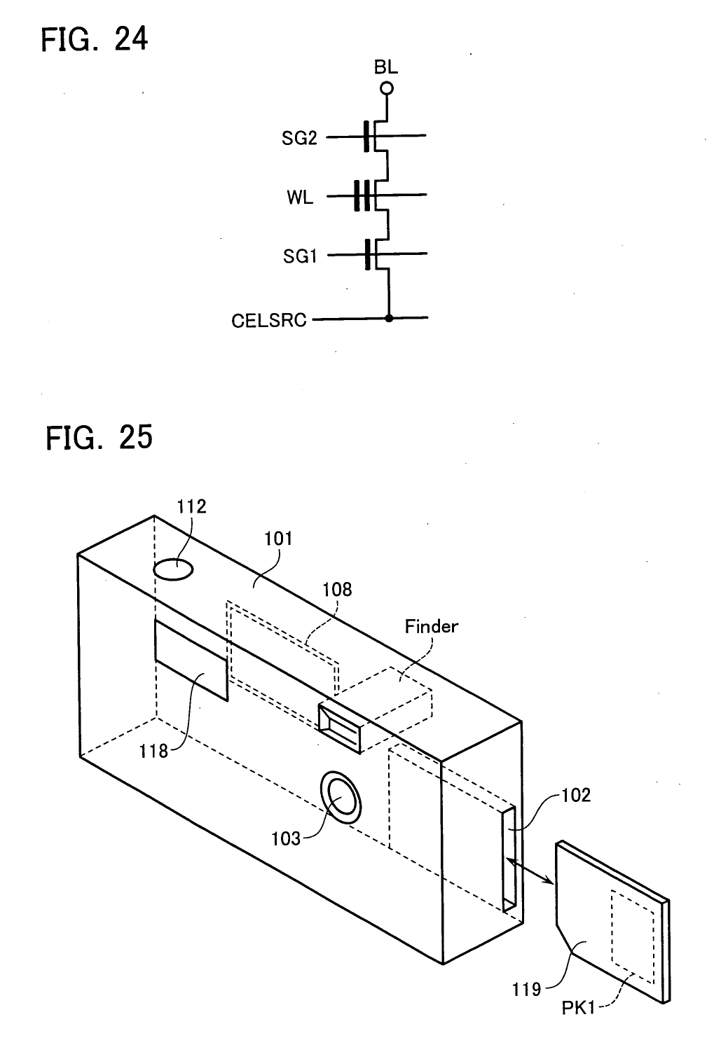

The number of memory cells configuring a NAND cell in a block is arbitrary. For example, as shown in FIG. 24, one memory cell may configure a NAND cell. Accordingly, a block group consisting of blocks grouped under the number of the memory cell configuring the NAND cell equal to one may be contained in the block groups shown in FIG. 23.

### Applications to Electronic Card and Electronic Device

As an embodiment, an electronic card using the non-volatile semiconductor memory devices according to the above-described embodiments of the present invention and an electronic device using the card will be described bellow.

FIG. 25 shows an electronic card according to this embodiment and an arrangement of an electronic device using this card. This electronic device is a digital still camera 101 as an example of portable electronic devices. The electronic card is a memory card 51 used as a recording medium of the digital still camera 101. The memory card 51 incorporates an IC package PK1 in which the non-volatile semiconductor memory device or the memory system according to the above-described embodiment is integrated or encapsulated.

The case of the digital still camera 101 accommodates a card slot 102 and a circuit board (not shown) connected to this card slot 102. The memory card 51 is detachably inserted into the card slot 102 of the digital still camera 101. When inserted in the slot 102, the memory card 51 is electrically connected to electric circuits of the circuit board.

If this electronic card is a non-contact type IC card, it is electrically connected to the electric circuits on the circuit board by radio signals when inserted in or approached to the card slot 102.

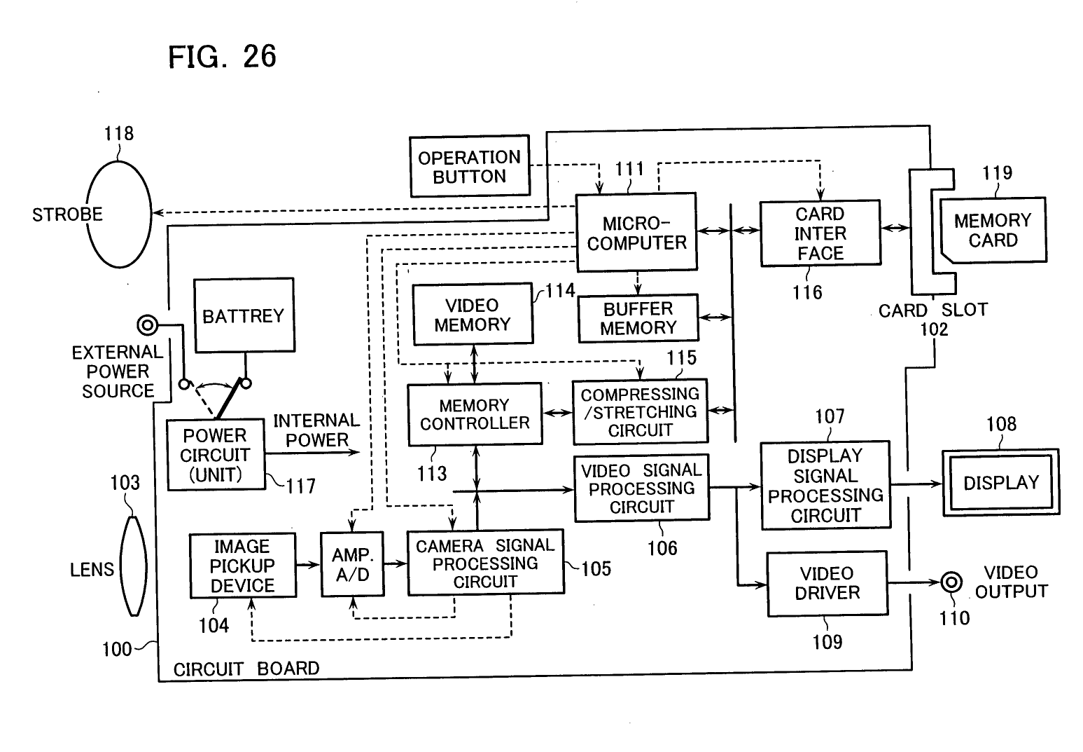

FIG. 26 shows a basic arrangement of the digital still camera. Light from an object is converged by a lens 103 and input to an image pickup device 104. The image pickup device 104 is, for example, a CMOS sensor and photoelectrically converts the input light into, for example, an analog output signal. This analog signal is amplified by an analog amplifier (AMP), and converted into a digital signal by an A/D converter (A/D). The converted signal is input to a camera signal processing circuit 105 where the signal is subjected to automatic exposure control (AE), automatic white balance control (AWB), color separation, and the like, and converted into a luminance signal and color difference signals.

To monitor the image, the output signal from the camera processing circuit 105 is input to a video signal processing circuit 106 and converted into a video signal. The system of the video signal is, e.g., of NTSC (National Television System Committee). The video signal is input to a display 108 attached to the digital still camera 101 via a display signal processing circuit 107. The display 108 is, e.g., a liquid crystal monitor.

The video signal is supplied to a video output terminal 110 via a video driver 109. An image picked up by the digital still camera 101 can be output to an image apparatus such as a television set via the video output terminal 110. This allows the pickup image to be displayed on an image apparatus other than the display 108. A microcomputer 111 controls the image pickup device 104, the analog amplifier (AMP), the A/D converter (A/D), and the camera signal processing circuit 105.

To capture an image, an operator presses an operation button such as a shutter button 112. In response to this operation, the microcomputer 111 controls a memory controller 113 to write the output signal from the camera signal processing circuit 105 into a video memory 114 as a frame image. The frame image written in the video memory 114 is compressed on the basis of a predetermined compression format by a compressing/stretching circuit 115. The compressed image is recorded, via a card interface 116, on the memory card 51 inserted in the card slot.

To reproduce a recorded image, an image recorded on the memory card 51 is read out via the card interface 116, stretched by the compressing/stretching circuit 115, and written into the video memory 114. The written image is input to the video signal processing circuit 106 and displayed on the display 108 or another image apparatus in the same manner as when the image is monitored.

In this arrangement, mounted on the circuit board 100 are the card slot 102, the image pickup device 104, the analog amplifier (AMP), the A/D converter (A/D), the camera signal processing circuit 105, the video signal processing circuit 106, the display signal processing circuit 107, the video driver 109, the microcomputer 111, the memory controller 113, the video memory 114, the compressing/stretching circuit 115, and the card interface 116.

The card slot 102 is not mounted on the circuit board 100 necessarily, and can also be connected to the circuit board 100 by a connector cable or the like.

A power circuit 117 is also mounted on the circuit board 100. The power circuit 117 receives power from an external power source or battery and generates an internal power source voltage used inside the digital still camera 101. For example, a DC-DC converter can be used as the power circuit 117. The internal power source voltage is supplied to the respective circuits described above, and to a strobe 118 and the display 108.

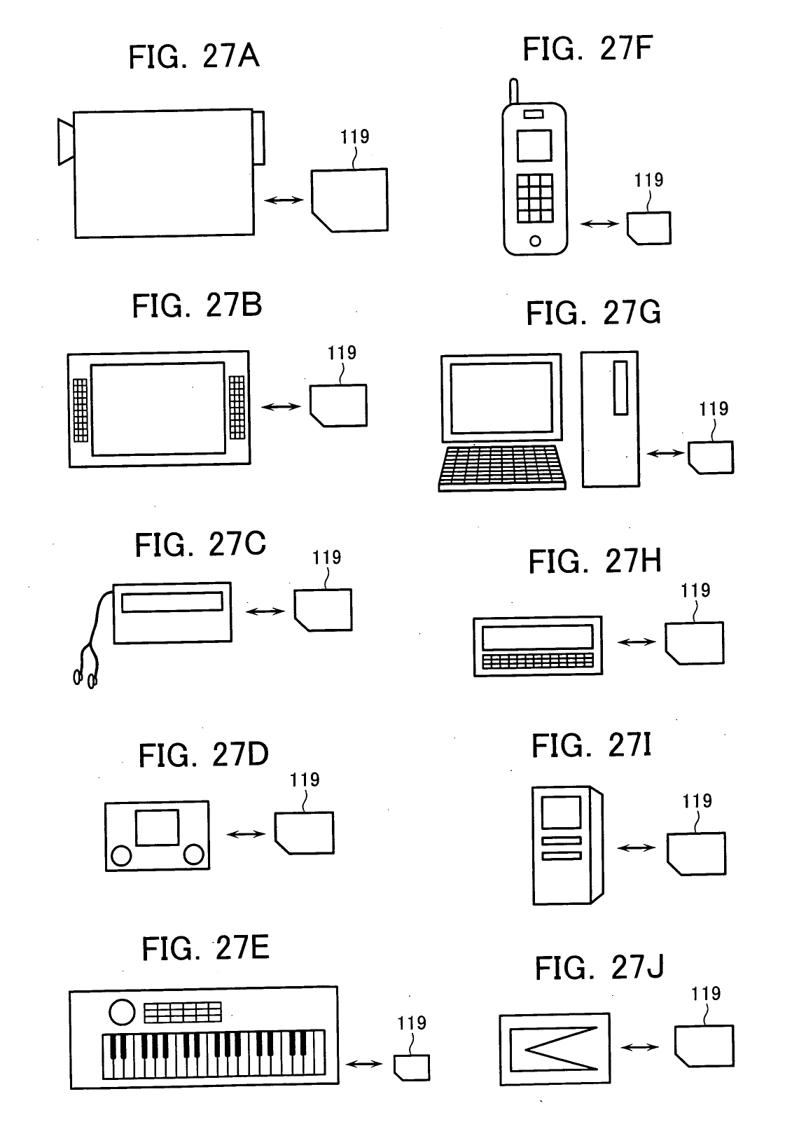

As described above, the electronic card according to this embodiment can be used in portable electronic devices such as the digital still camera explained above. However, the electronic card can also be used in various apparatus such as those shown in FIGS. 27A to 27J, as well as in portable electronic devices. That is, the electronic card can also be used in a video camera shown in FIG. 27A, a television set shown in FIG. 27B, an audio apparatus shown in FIG. 27C, a game apparatus shown in FIG. 27D, an electronic musical instrument shown in FIG. 27E, a cell phone shown in FIG. 27F, a personal computer shown in FIG. 27G, a personal digital assistant (PDA) shown in FIG. 27H, a voice recorder shown in FIG. 27I, and a PC card shown in FIG. 27J.

While the present invention has been particularly shown and described with reference to the embodiments, it will be understood by those skilled in the art that various changes in form and detail may be made without departing from the spirit, scope, and teachings of the invention.

As described above, the present invention is provided with block groups each consisting of blocks grouped under the number of memory cells configuring a NAND cell, which is the same as others in one block group and different from those in other block groups. This is effective to achieve an increased capacity together with an improved erase efficiency.

1. A non-volatile semiconductor memory device operative to erase data on a block basis, in which each of blocks includes a plurality of NAND cells each having one or more electrically erasable programmable memory cells and selection transistors arranged at both ends thereof, said memory device comprising:
a plurality of block groups each consisting of said blocks grouped under the number of said memory cells configuring said NAND cell, which is the same as others in one block group and different from those in other block groups; and
a row selector arranged to select said memory cells located on the same row in each block in said plurality of block groups, wherein neighbors of said blocks individually include said selection transistors not shared.

2. The non-volatile semiconductor memory device according to claim 1, further comprising:
a plurality of word lines each connected to said memory cells located on the same row in each block in said plurality of block groups; and
a plurality of drive lines each arranged to supply a voltage to said word line, wherein said row selector includes transfer transistors each serving as a switch operative to connect said word line to said drive line.

3. The non-volatile semiconductor memory device according to claim 1, said plurality of block groups including:
a first block group consisting of said blocks grouped under the number of said memory cells configuring said NAND cell equal to m; and
a second block group consisting of said blocks grouped under the number of said memory cells configuring said NAND cell equal to n (where n=km; k is an integer of 2 or more).

4. The non-volatile semiconductor memory device according to claim 3, wherein k blocks in said first block group and one block in said second block group share said drive lines.

5. The non-volatile semiconductor memory device according to claim 3, wherein gate electrodes of said transfer transistors are commonly connected to said row selector corresponding to said k blocks.

6. The non-volatile semiconductor memory device according to claim 3, wherein said second block group is divided into two and located separately, interposing first block group therebetween.

7. The non-volatile semiconductor memory device according to claim 3, wherein a storage region for a product-specified ID of a semiconductor chip containing said non-volatile semiconductor memory device is assigned to at least one of said blocks in said first block group.

8. The non-volatile semiconductor memory device according to claim 3, wherein a storage region for a parameter defining circuit operation of said non-volatile semiconductor memory device is assigned to at least one of said blocks in said first block group.

9. The non-volatile semiconductor memory device according to claim 1, further comprising a cell array including said plurality of block groups arranged in the column direction, wherein blocks located at both sides of said cell array in the column direction include dummy NAND cells not connected to said row selector.

10. The non-volatile semiconductor memory device according to claim 1, the number of said memory cells configuring said NAND cell is equal to a power of two.

11. The non-volatile semiconductor memory device according to claim 1, said plurality of block groups including a block group consisting of said blocks grouped under the number of said memory cell configuring said NAND cell equal to one.

12. An electronic card including said non-volatile semiconductor memory device according to claim 1 as mounted thereon.

13. An electronic device, comprising:
a card interface;
a card slot connected to said card interface; and
said electronic card according to claim 12 electrically connectable to said card slot.

14. The electronic device according to claim 13, wherein said electronic device comprises a digital camera.
